(19) United States
(12) Patent Application Publication
(10) Pub. No.: US 2004/0140498 A1
(43) Pub. Date: Jul. 22, 2004

(54) Dual-bit nitride read only memory cell

(76) Inventor: Tsong-Minn Hsieh, Miao-Li City (TW)

Correspondence Address: NAIPO (NORTH AMERICA INTERNATIONAL PATENT OFFICE), P.O. BOX 506, MERRIFIELD, VA, 22116, US

(21) Appl. No.: 10/460,239

(22) Filed: Jun. 13, 2003

(30) Foreign Application Priority Data
Jan. 20, 2003 (TW) 092101065

(51) Int. Cl. H01L 29/788

(52) U.S. Cl. 257/316

(57) ABSTRACT

A dual-bit nitride read only memory (NROM) cell is provided. The NROM cell includes a substrate. A first oxide-nitride-oxide (ONO) layer and a second ONO layer are positioned on the substrate respectively, the first ONO layer and the second ONO layer being separated by a predetermined region. A first control gate is positioned on the first ONO layer and a second control gate is positioned on the second ONO layer. A select gate is positioned on the substrate within the predetermined region. Two conductive areas are positioned in the substrate adjacent to the first ONO layer and the second ONO layer respectively, functioning as a source and a drain of the NROM cell.

### CROSS REFERENCE TO RELATED APPLICATIONS

### BACKGROUND OF INVENTION

1. Field of the Invention

The present invention relates to a dual-bit nitride read only memory (NROM) cell, and more particularly, to a dual-bit NORM cell with a select gate.

2. Description of the Prior Art

Differing from other types of ROMs that use a polysilicon or metal floating gate, an NROM uses an insulating dielectric layer of silicon nitride as a charge-trapping medium. Due to the highly compacted nature of the silicon nitride layer, hot electrons tunneling from the MOS transistor into the silicon nitride layer are trapped to form an unequal concentration distribution so as to store data in the NROM and adjust a threshold voltage Vₜₕ of the NROM as well.

Please refer to FIG. 1 of a cross-sectional diagram of an NROM cell according to the prior art. As shown in FIG. 1, the NROM cell includes a substrate 10, an ONO layer, composed of an oxide layer 12, a nitride layer 14 and an oxide layer 16, positioned on a surface of the substrate 10, a control gate 18 positioned on a surface of the oxide layer 16, and two conductive areas 20 and 22, functioning as a source and a drain respectively, positioned in the substrate 10 to surround the ONO layer. The left side and the right side of the nitride layer 14 are used to store 1-bit data Bit-1 and another 1-bit data Bit-2, respectively. The middle portion of the nitride layer 14 is used as insulation to insulate Bit-1 and Bit-2 from each other.

Depending on Bit-1 storing 0 or 1, a threshold voltage to access Bit-1 varies. Generally, a positive voltage between the threshold voltages to access 0 and 1 is supplied to the control gate 18, so that the data stored in Bit-1 can be determined by measuring the channel currents. When accessing Bit-2, a positive voltage between the threshold voltages to access 0 and 1 is supplied to the control gate 18, so that the data stored in Bit-2 can be determined by measuring the channel currents. Bit-1 and Bit-2 are stored at different sides of the nitride layer 14. However, as the integration of integrated circuits increases, the entire size including the channel length of the NROM reduces. In this case, Bit-1 and Bit-2 are too close to avoid read interference from each other. For example, if positions of Bit-1 and Bit-2 are too close, it is hard to find currents of different values from specific regions of the short channel. As a result, it is difficult to distinguish Bit-1 and Bit-2 store 0 and 1, or store 1 and 0, respectively. In addition, charges stored in Bit-1 and Bit-2 may have lateral migration to each other because of the short channel length or the highly access frequency of the NROM cell, thus reducing reliability of the NROM cell.

### SUMMARY OF INVENTION

It is therefore an objective of the claimed invention to provide a dual-bit NROM cell with a select gate to prevent read interference between the two bits and improve reliability of the NROM cell.

According to the claimed invention, the NROM cell includes a first ONO layer and a second ONO layer positioned on a substrate respectively, the first ONO layer and the second ONO layer being separated by a predetermined region. A first control gate is positioned on the first ONO layer and a second control gate is positioned on the second ONO layer. A select gate is positioned on the substrate within the predetermined region. Two conductive areas are positioned in the substrate adjacent to the first ONO layer and the second ONO layer respectively, functioning as a source and a drain of the NROM cell.

It is an advantage of the present invention that the first ONO layer stores 1-bit data Bit-1 and the second ONO layer stores another 1-bit data Bit-2, respectively. When writing or reading Bit-1, the second control gate and the select gate are used as pass gates. When writing or reading Bit-2, the first control gate and the select gate are used as pass gates. Therefore, Bit-1 and Bit-2 can be read or written precisely to prevent read interference from the other to improve reliability of the NROM cell.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a cross-sectional diagram of an NORM cell according to the prior art; and

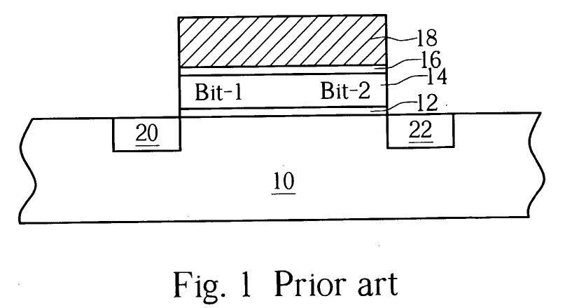

FIG. 2 is a cross-sectional diagram of an NORM cell according to the present invention.

### DETAILED DESCRIPTION

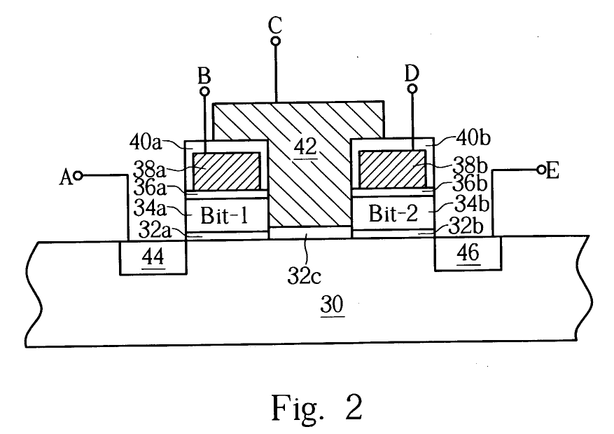

Please refer to FIG. 2 of a cross-sectional diagram of an NROM cell according to the present invention. As shown in FIG. 2, the NROM cell includes a first ONO layer positioned on a left side of a substrate 30. The first ONO layer is composed of an oxide layer 32a, a nitride layer 34a and an oxide layer 36a, and is used to store 1-bit data Bit-1. In addition, the NROM cell further includes a second ONO layer positioned on a right side of the substrate 30. The second ONO layer is composed of an oxide layer 32b, a nitride layer 34b and an oxide layer 36b, and is used to store another 1-bit data Bit-2.

A control gate 38a and a control gate 38b are positioned on the oxide layer 36a and the oxide layer 36b, respectively. A dielectric layer 40a and a dielectric layer 40b are positioned on the first ONO layer and the second ONO layer, respectively. A select gate 42 is positioned on a surface of an oxide layer 32c above the substrate 30 and covers portions of the dielectric layer 40a and the dielectric layer 40b. Two conductive areas 44 and 46, functioning as a source and a drain, are positioned within the substrate 30 adjacent to the first ONO layer and the second ONO layer, respectively.

An operation method of the NROM cell of the present invention is introduced below. When writing/programming data Bit-1 inside the nitride layer 34a, a positive voltage higher than the threshold voltage is supplied to the node C connecting to the select gate 42 and to the node D connecting to the control gate 38b. As a result, the select gate 42 and the control gate 38b are open and used as pass gates. The node E connecting to the conductive area 46 (source) is grounded. A suitable positive voltage is supplied to the node A connecting to the conductive area 44 (drain). A positive voltage higher than the threshold voltage is also supplied to the node B connecting to the control gate 38a. As a result, channel currents occur between the source and the drain, and channel hot electrons may inject to the nitride layer 34a to complete writing/programming Bit-1. The operation method of writing/programming Bit-2 is similar to the method of Bit-1. The suggestion values of the operating voltages supplied to the nodes are listed below:

(1) When writing/programming Bit-1, the nodes A and B are supplied with approximately 5V, the nodes C and D are supplied with approximately 6V, and the node E is grounded; and

(2) When writing/programming Bit-2, the nodes D and E are supplied with approximately 5V, the nodes B and C are supplied with approximately 6V, and the node A is grounded.

When deleting data from Bit-1, a negative voltage is supplied to the node B connecting to the control gate 38a or the node B can be grounded. A positive voltage is supplied to the node A connecting to the conductive area 44 (drain) to inject hot holes to the nitride layer 34a and neutralize electrons stored in the nitride layer 34a, thus completing data deletion from Bit-1. The operation method of deleting data from Bit-2 is similar to the method of Bit-1.

When reading data Bit-1 inside the nitride layer 34a, a positive voltage higher than the threshold voltage is supplied to the node C connecting to the select gate 42 and to the node D connecting to the control gate 38b. As a result, the select gate 42 and the control gate 38b are open and used as pass gates. The node E connecting to the conductive area 46 (source) is grounded. A suitable positive voltage is supplied to the node A connecting to the conductive area 44 (drain) A positive voltage between the threshold voltage to access 0 and the threshold voltage to access 1 is supplied to the node B connecting to the control gate 38a. As a result, the values of the threshold voltage of Bit-1 and the channel currents are determined by charges stored in the nitride layer 34a, thus completing read of Bit-1. The operation method of reading Bit-2 is similar to the method of Bit-1. The suggestion values of the operating voltages supplied to the nodes are listed below:

(1) When reading Bit-1, the node A is supplied with approximately 1V, the node B is supplied with approximately 3V, the nodes C and D are supplied with approximately 5V, and the node E is grounded; and

(2) When reading Bit-2, the node E is supplied with approximately 1V, the node D is supplied with approximately 3V, the nodes B and C are supplied with approximately 5V, and the node A is grounded.

In contrast to the NROM cell of the prior art, the present invention inserts the select gate between the first ONO layer and the second ONO layer and uses the select gate as a pass gate when writing or reading data in the ONO layers. Therefore, data stored in the ONO layers can be read or written precisely to prevent read interference between the two bits of the NROM cell and so as to improve reliability of the NROM cell.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A dual-bit nitride read only memory (NROM) cell comprising:
a substrate;
a first ONO layer and a second ONO layer positioned on the substrate respectively, the first ONO layer and the second ONO layer being separated by a predetermined region;
a first control gate positioned on the first ONO layer and a second control gate positioned on the second ONO layer;
a select gate positioned on the substrate within the predetermined region; and
two conductive areas positioned in the substrate adjacent to the first ONO layer and the second ONO layer respectively, functioning as a source and a drain of the NROM cell.

2. The NROM cell of claim 1 further comprising a dielectric layer positioned on the first control gate and the second control gate.

3. The NROM cell of claim 2 wherein the select gate covers portions of the dielectric layer.

4. The NROM cell of claim 1 wherein the first ONO layer stores 1-bit data Bit-1 and the second ONO layer stores another 1-bit data Bit-2.

5. The NROM cell of claim 4 wherein the second control gate and the select gate are used as pass gates when writing or reading Bit-1.

6. The NROM cell of claim 4 wherein the first control gate and the select gate are used as pass gates when writing or reading Bit-2.

7. An NROM cell with a select gate, the NROM cell comprising:
a substrate;
a plurality of ONO layers positioned on the substrate;
a plurality of control gates positioned on the ONO layers;
two conductive areas positioned in the substrate adjacent to the ONO layers; and
at least a select gate positioned on the substrate between two of the ONO layers.

8. The NROM cell of claim 7 further comprising a dielectric layer positioned on the control gates.

9. The NROM cell of claim 8 wherein the select gate covers portions of the dielectric layer.

10. The NROM cell of claim 7 wherein the ONO layers comprise a first ONO layer to store 1-bit data Bit-I and a second ONO layer to store another 1-bit data Bit-2.

11. The NROM cell of claim 10 wherein the control gates comprise a first control gate positioned on the first ONO layer and a second control gate positioned on the second ONO layer.

12. The NROM cell of claim 11 wherein the second control gate and the select gate are used as pass gates when writing or reading Bit-1.

13. The NROM cell of claim 11 wherein the first control gate and the select gate are used as pass gates when writing or reading Bit-2.
